(19) United States
(12) Patent Application Publication
(10) Pub. No.: US 2020/0035674 A1
(43) Pub. Date: Jan. 30, 2020

(54) GATE CUT LAST PROCESSING WITH SELF-ALIGNED SPACER

(71) Applicant: QUALCOMM Incorporated, San Diego, CA (US)

(72) Inventors: Ye LU, San Diego, CA (US); Haining YANG, San Diego, CA (US)

(21) Appl. No.: 16/277,751

(22) Filed: Feb. 15, 2019

Related U.S. Application Data
(60) Provisional application No. 62/703,827, filed on Jul. 26, 2018.

(51) Int. Cl. H01L 27/088; H01L 29/78; H01L 29/66; H01L 29/06; H01L 21/8234

(52) U.S. Cl. CPC H01L 27/0886; H01L 29/785; H01L 21/823468; H01L 29/0649; H01L 21/823431; H01L 29/66795

(57) ABSTRACT

A fin field effect transistors (FinFET) array includes a first transistor having a fin and a first conductive gate on the fin. The FinFET array also includes a second transistor having another fin and a second conductive gate on the other fin. The FinFET array further includes a first dielectric material and a self-aligned dielectric spacer. The first dielectric material is between the first transistor and the second transistor and on at least a portion of sidewalls of each of the first conductive gate and the second conductive gate. The self-aligned dielectric spacer is on at least a portion of the sidewalls of each of the first conductive gate and the second conductive gate.

### CROSS-REFERENCE TO RELATED APPLICATION

The present application claims the benefit of U.S. Provisional Patent Application No. 62/703,827, filed on Jul. 26, 2018, and titled “GATE CUT LAST PROCESSING WITH SELF-ALIGNED SPACER,” the disclosure of which is expressly incorporated by reference herein in its entirety.

### BACKGROUND

### Field

Aspects of the present disclosure relate to semiconductor devices, and more particularly to fin field effect transistors (FinFET) and gate all around (GAA) transistors having a self-aligned spacer.

### Background

In fin field effect transistor (FinFET) technology, a polysilicon gate is first patterned across the whole wafer, followed by performing a gate cut. After performing other processes including but not limited to source/drain formation, halo implant doping, etc., the already cut polysilicon gate is removed, leaving behind a cavity that is filled with a high-K metal gate. This process is referred to as a gate-first process. An issue with the gate-first process is that as the chip area continues to be scaled (or reduced) and the semiconductor devices continue to shrink in size, the gate-first process leaves very little room for the metal gate filling. The lack of room for the metal gate filling may cause process issues, particularly in five-nanometer technology and below.

### SUMMARY

A transistor array includes a first transistor having a first fin and a first conductive gate on the first fin. The transistor array also includes a second transistor having a second fin and a second conductive gate on the second fin. The transistor array further includes a first dielectric material between the first transistor and the second transistor and on at least a portion of sidewalls of each of the first conductive gate and the second conductive gate. Furthermore, the transistor array includes a self-aligned dielectric spacer on at least a portion of the sidewalls of each of the first conductive gate and the second conductive gate.

A method for fabricating a transistor array includes fabricating a first transistor having a first fin and a first conductive gate on the first fin. The method also includes fabricating a second transistor having a second fin and a second conductive gate on the second fin. The method further includes forming self-aligned dielectric spacers on sidewalls of each of the first conductive gate and the second conductive gate. Furthermore, the method includes depositing a first dielectric material on the self-aligned dielectric spacers between the first transistor and the second transistor and on at least a portion of sidewalls of each of the first conductive gate and the second conductive gate.

A transistor array includes a first transistor having a first fin and a first conductive gate on the first fin. The transistor array also includes a second transistor having a second fin and a second conductive gate on the second fin. The transistor array further includes means for insulating the first transistor from the second transistor. The insulating means is between the first transistor and the second transistor and on at least a portion of sidewalls of each of the first conductive gate and the second conductive gate. Furthermore, the transistor array includes a self-aligned dielectric spacer on at least a portion of the sidewalls of each of the first conductive gate and the second conductive gate.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer in an aspect of the present disclosure.

FIG. 2 illustrates a cross-sectional view of a die in accordance with an aspect of the present disclosure.

FIG. 3 illustrates a cross-sectional view of a metal-oxide-semiconductor field effect transistor (MOSFET) device in an aspect of the present disclosure.

FIG. 4 illustrates a fin field effect transistor (FinFET).

FIG. 5 illustrates an exemplary fin field effect transistor (FinFET) array, according to aspects of the present disclosure.

FIGS. 6A-6J are exemplary diagrams illustrating stages of a method for fabricating a transistor array, according to an aspect of the present disclosure.

FIG. 7 illustrates a method for fabricating a transistor array, according to aspects of the present disclosure.

FIG. 8 is a block diagram showing an exemplary wireless communication system in which an aspect of the disclosure may be advantageously employed.

FIG. 9 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

In fin field effect transistor (FinFET) technology, a polysilicon gate is first patterned across the whole wafer, followed by performing a gate cut. After performing other processes including but not limited to source/drain formation, halo implant doping, etc., the already cut polysilicon gate is removed, leaving behind a cavity that is filled with a high-K metal gate. This process is referred to as a gate-cut first process. An issue with the gate-cut first process is that as the chip area continues to be scaled (or reduced) and the semiconductor devices continue to shrink in size, the gate-cut first process leaves very little room for metal gate filling. The lack of room for the metal gate filling may cause process issues, particularly in five-nanometer technology.

One solution to mitigate the process issues (e.g., the metal fill issue) is a gate-cut last process instead of the gate-cut first process. In the gate-cut last process, the polysilicon gate is processed by removing polysilicon to create a cavity that is filled with the high-K metal gate. For example, the metal is deposited in the cavity and then a lithography mask and etch are used to cut unnecessary portions of the gate. However, the gate-cut last process involves intense metal etching on the high-K metal gate. Moreover, the etching is not self-aligned. As a result, the etching damages the high-K metal and work function metal on a side of a fin of the FinFET, which causes significant process issues. Accordingly, aspects of the present disclosure are directed to reducing the process issues associated with the gate-cut last process.

In one aspect of the disclosure, a FinFET array includes a first transistor having a fin and a first conductive gate on the fin. The FinFET array also includes a second transistor having another fin and a second conductive gate on the other fin. The FinFET array further includes a first dielectric and a self-aligned dielectric spacer. The first dielectric material is between the first transistor and the second transistor and on at least a portion of sidewalls of each of the first conductive gate and the second conductive gate. The self-aligned dielectric spacer is on at least a portion of the sidewalls of each of the first conductive gate and the second conductive gate. The first dielectric material may be silicon nitride (SiN). The self-aligned dielectric spacer may be a low-K dielectric material such as a low-K spin on material. Although the preceding description has been with respect to FinFETs, other technologies, such as gate all around (GAA) transistors, also benefit from having a self-aligned spacer.

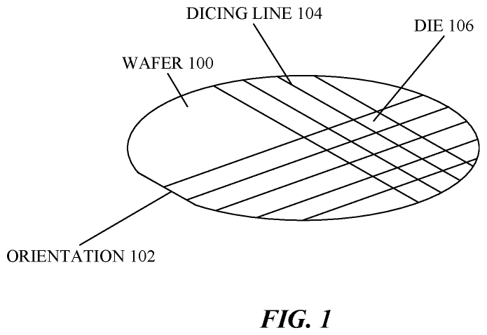

FIG. 1 illustrates a perspective view of a semiconductor wafer in which a transistor array with gate-cut last is fabricated according to an aspect of the present disclosure. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a compound material, such as gallium arsenide (GaAs) or gallium nitride (GaN), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in

FIG. 1, or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and l, which are the Miller indices for a plane (hkl) in the crystal. Each index denotes a plane orthogonal to a direction (h, k, l) in the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to l. For some crystals, negative numbers are used (written as a bar over the index number) and for some crystals, such as gallium nitride, more than three numbers may be employed to adequately describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

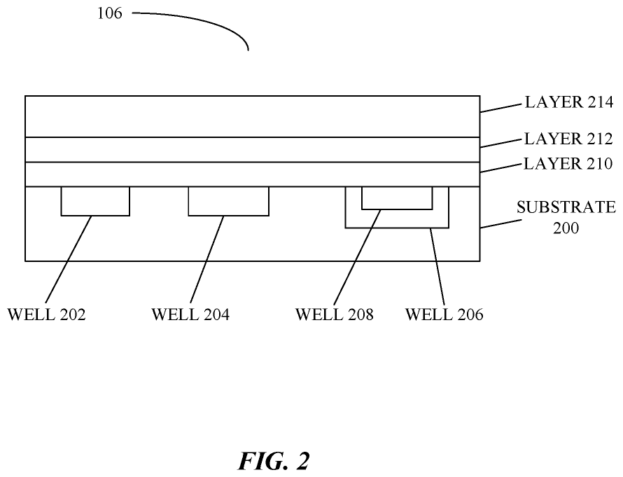

FIG. 2 illustrates a cross-sectional view of a die 106 in accordance with an aspect of the present disclosure. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within a substrate 200 (e.g., a semiconductor substrate), there may be wells 202 and 204, which may be the source and/or drain of a field effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have wells 206 and 208. The well 208 may be completely within the well 206, and, in some cases, may form a bipolar junction transistor (BJT). The well 206 may also be used as an isolation well to isolate the well 208 from electric and/or magnetic fields within the die 106.

Layers 210 through 214 may be added to the die 106. The layer 210 may be, for example, an oxide or insulating layer that may isolate the wells 202-208 from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers 210 and 214. The layer 214 may be an encapsulating layer, which may protect the layers 210 and 212, as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers 210-214. For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers 210-214, and through selective removal, material selection, and dopant concentration of the substrate 200 and the wells 202-208, many different structures and electronic devices may be formed within the scope of the present disclosure.

Further, the substrate 200, the wells 202-208, and the layers 210-214 may be selectively removed or added through various processes. Chemical wet etching, chemical mechanical planarization (CMP), plasma etching, photoresist masking, damascene processes, and other methods may create the structures and devices of the present disclosure.

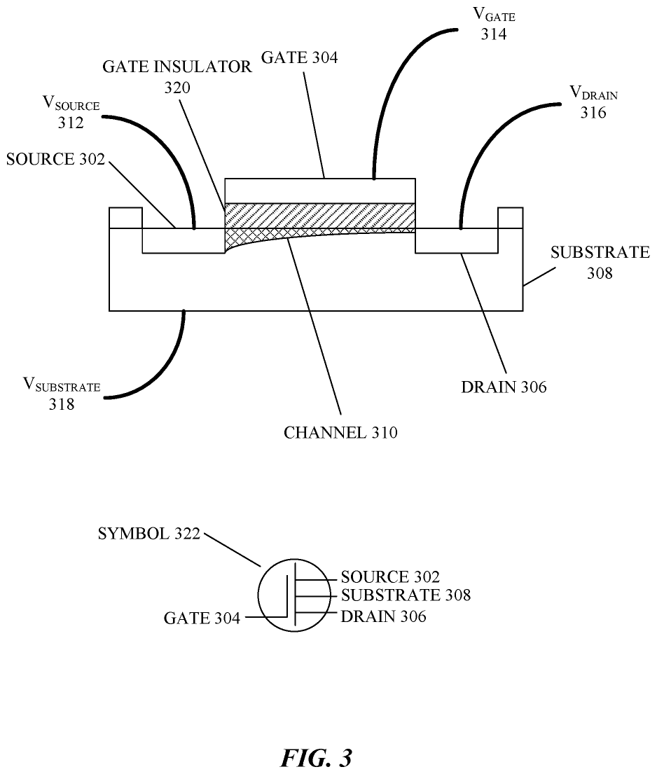

FIG. 3 illustrates a cross-sectional view of a metal-oxide-semiconductor field effect transistor (MOSFET) device 300 in an aspect of the present disclosure. The MOSFET device 300 may have four input terminals. The four inputs are a source 302, a gate 304, a drain 306, and a substrate 308. The source 302 and the drain 306 may be fabricated as the wells 202 and 204 in the substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but substrate 308 may also be one or more of the layers 210-214 that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

The gate 304 may also be made of different materials. In some designs, the gate 304 is made from polycrystalline silicon, also referred to as polysilicon or poly, which is a conductive form of silicon. Although referred to as “poly” or “polysilicon” herein, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304 as described in the present disclosure.

To interconnect to the MOSFET device 300, or to interconnect to other devices in the die 106 (e.g., semiconductor), interconnect traces or layers are used. These interconnect traces may be in one or more of layers 210-214, or may be in other layers of the die 106.

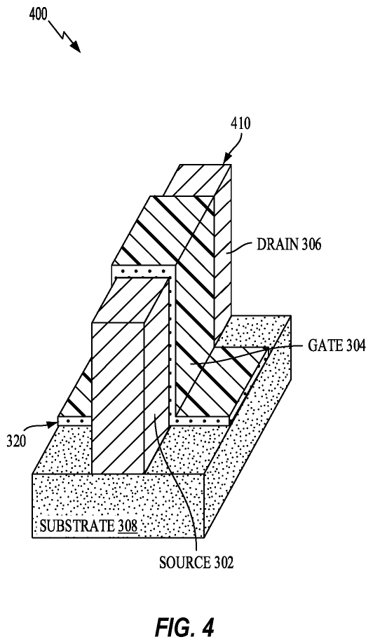

FIG. 4 illustrates a fin-structured FET (FinFET 400) that operates in a similar fashion to the MOSFET device 300 described with respect to FIG. 3. A fin 410 in a FinFET 400 is grown or otherwise coupled to the substrate 308. The substrate 308 may be a semiconductor substrate or other like supporting layer, for example, comprised of an oxide layer, a nitride layer, a metal oxide layer or a silicon layer. The fin 410 includes the source 302 and the drain 306. A gate 304 is over the fin 410 and on the substrate 308 with a gate insulator 320 between. A FinFET transistor is a 3D fin-based metal-oxide-semiconductor field effect transistor (MOSFET). As a result, the physical size of the FinFET 400 may be smaller than the MOSFET device 300 structure shown in FIG. 3. This reduction in physical size allows for more devices per unit area on the die 106.

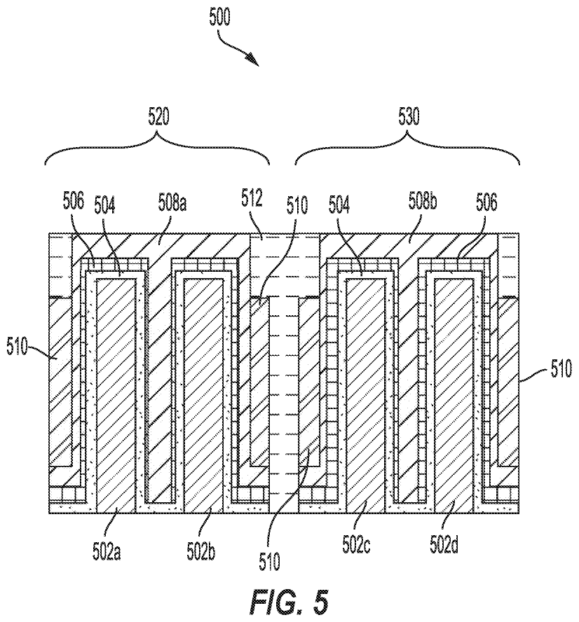

FIG. 5 illustrates an exemplary transistor array 500, according to aspects of the present disclosure. Various aspects of the present disclosure are directed to a self-aligned protected gate-cut last process for fabricating the transistor array 500. The transistor array 500 is fabricated according to the self-aligned protected gate-cut last process and includes a first transistor 520 and a second transistor 530. The transistor array 500 includes fins 502a, 502b, 502c, and 502d, a high-K metal 504 on the fins 502a, 502b, 502c, and 502d, a metal gate work function 506 on the high-K metal 504, gate metal 508a and 508b on the metal gate work function 506, dielectric protection layer(s) 510 (or self-aligned dielectric spacer(s)) on one or more sidewalls of one or more gate structures and a dielectric 512 between gates that are to be separated (e.g., by etching).

In one aspect of the disclosure, the first transistor 520 includes the fin 502a and the fin 502b as well as a first conductive gate that includes a first gate conductive deposit on the fin 502a and the fin 502b. The first gate conductive deposit may include multiple layers of conductive material. For example, the first gate conductive deposit may include the metal gate work function 506, the high-K metal 504, and the gate metal 508a. The metal gate work function 506 is between the high-K metal 504 and the gate metal 508a. The materials of each of the metal gate work function 506, the high-K metal 504, and the gate metal 508a may be different. Examples of materials for the metal gate work function include tantalum nitride (TaN), titanium nitride (TiN), lanthanum oxide (LaO) as well as doped TaN and doped TiN.

The second transistor 530 includes the fin 502c and the fin 502d as well as a second conductive gate that includes a second gate conductive deposit on the fin 502c and the fin 502d. The second gate conductive deposit also includes multiple layers of conductive material. For example, the second gate conductive deposit includes the metal gate work function 506, the high-K metal 504, and the gate metal 508b. The metal gate work function 506 is between the high-K metal 504 and the gate metal 508b.

The dielectric 512 is between the first transistor 520 and the second transistor 530 and on at least a portion of sidewalls of each of the first conductive gate (e.g., the gate metal 508a) and the second conductive gate (e.g., the gate metal 508b). The self-aligned dielectric spacer (e.g., dielectric protection layer(s) 510) is on at least a portion of the sidewalls of each of the first conductive gate and the second conductive gate. The dielectric 512 may be silicon nitride (SiN). The dielectric protection layer(s) 510 may be a low-K dielectric material such as a low-K spin-on material. Although the preceding description has been with respect to FinFETs, other technologies, such as gate all around (GAA) transistors, also benefit from having a self-aligned spacer.

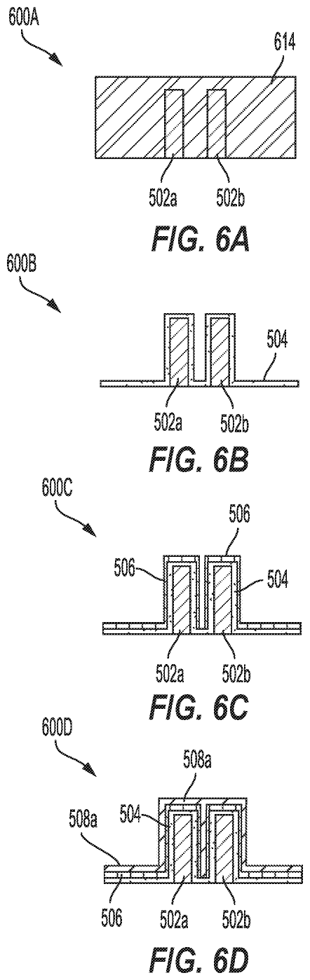

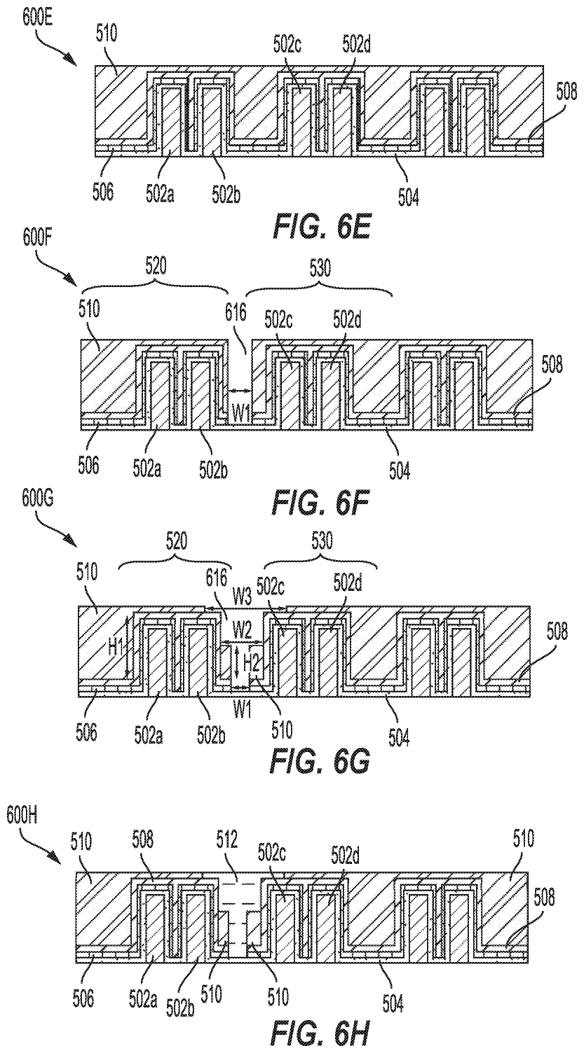

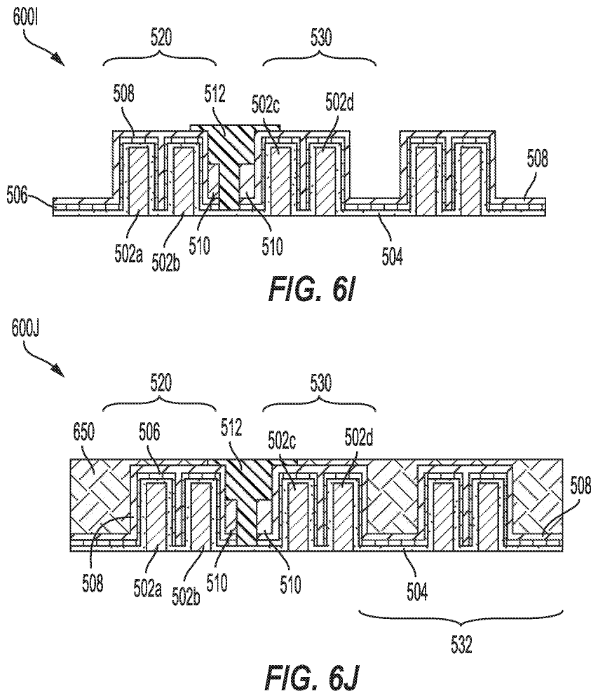

FIGS. 6A-6J are exemplary diagrams illustrating stages of a method for fabricating a transistor array, according to an aspect of the present disclosure. For illustrative purposes, some of the labelling and numbering of the devices and features of FIGS. 6A-6J are similar to those of FIG. 5. For example, the stages of the fabrication method are shown as cross-sectional views of formation of the transistor array 500.

Referring to FIG. 6A, a first stage of the method for fabricating the transistor array is depicted and generally designated 600A. FIG. 6A illustrates a polysilicon material 614 deposited on the fin 502a and the fin 502b to form a polysilicon gate on the fin 502a and the fin 502b. Although only a single transistor region is shown in FIG. 6A, the polysilicon gate is patterned across multiple transistor regions of a whole wafer.

Referring to FIG. 6B, a second stage of the method for fabricating the transistor array is depicted and generally designated 600B. FIG. 6B illustrates removal of the polysilicon material 614 to create a region and cavity that is filled with a gate conductive deposit. For example, after the removal of the polysilicon material 614, the high-K metal 504 is deposited on the fin 502a and the fin 502b in the region and cavity previously filled with the polysilicon material 614. Although only a single transistor region is shown in FIG. 6B, the polysilicon material 614 is removed across multiple transistor regions of the wafer and the high-K metal 504 is deposited across multiple transistor regions of the wafer.

Referring to FIG. 6C, a third stage of the method for fabricating the transistor array is depicted and generally designated 600C. FIG. 6C illustrates filling the region and cavity created by the removal of the polysilicon material 614 with an additional gate conductive deposit. For example, the metal gate work function 506 is deposited on the high-K metal 504. Although only a single transistor region is shown in FIG. 6C, the polysilicon material 614 is removed across multiple transistor regions of the wafer and the metal gate work function 506 is deposited across multiple transistor regions (e.g., a transistor region of the first transistor 520 and the second transistor 530) of the whole wafer.

Referring to FIG. 6D, a fourth stage of the method for fabricating the transistor array is depicted and generally designated 600D. FIG. 6D illustrates further filling the region and cavity created by the removal of the polysilicon material 614 with an additional gate conductive deposit. For example, the gate metal 508a is deposited on the metal gate work function 506. The gate metal material can be aluminum, tungsten, cobalt or titanium in one example. Although only a single transistor region is shown in FIG. 6D, the polysilicon material 614 is removed across multiple transistor regions of the wafer and a gate metal (e.g., the gate metal 508a and the gate metal 508b) is deposited across multiple transistor regions (e.g., a transistor region of the first transistor 520 and the second transistor 530) of the wafer.

Referring to FIG. 6E, a fifth stage of the method for fabricating the transistor array is depicted and generally designated 600E. FIG. 6E illustrates depositing of a dielectric protection layer 510 on the gate conductive deposit. For example, the dielectric protection layer 510 is deposited on a gate metal 508. The gate metal 508 may include the gate metal 508a and the gate metal 508b deposited across multiple transistor regions (e.g., the transistor region of the first transistor 520 and the second transistor 530) of the wafer.

Referring to FIG. 6F, a sixth stage of the method for fabricating the transistor array is depicted and generally designated 600F. FIG. 6F illustrates etching of a gate cut region using a mask to create a cavity 616 between a first transistor region and a second transistor region of the wafer. The cavity may have a width W1. The cavity 616 is created between the first transistor 520 and the second transistor 530. For example, a portion of the dielectric protection layer 510, the gate metal 508, and the metal gate work function 506 are etched to create the cavity 616.

Referring to FIG. 6G, a seventh stage of the method for fabricating the transistor array is depicted and generally designated 600G. FIG. 6G illustrates recessing the gate cut region (to form a recessed gate cut region) with a mask to form spacers. For example, the gate cut region is further etched using a mask to pattern the cavity 616 between the first transistor region and the second transistor region of the wafer. The cavity 616 is patterned to introduce multiple widths (e.g., W1, W2, and W3) of the cavity 616. In one aspect, the portion of the dielectric protection layer 510 is further etched so that a height H2 of the dielectric protection layer 510 is shorter than a height H1 associated with the gate of the first transistor 520 and the second transistor 530.

Referring to FIG. 6H, an eighth stage of the method for fabricating the transistor array is depicted and generally designated 600H. FIG. 6H illustrates filling the cavity with the dielectric 512 (e.g., silicon nitride (SiN)). The dielectric 512 is then planarized by etching or chemical planarization (CMP).

Referring to FIG. 6I, a ninth stage of the method for fabricating the transistor array is depicted and generally designated 600I. FIG. 6I illustrates removing the dielectric protection layer(s) 510 in regions outside of the gate cut region.

Referring to FIG. 6J, a tenth stage of the method for fabricating the transistor array is depicted and generally designated 600J. FIG. 6J illustrates depositing a gate fill metal 650 (or fill gate conductive layer) and planarizing. The tenth stage 600J results in a transistor array where a portion of the transistor array is similar to the transistor array 500 of FIG. 5. Other portions (e.g., portion 532) of the transistor array of FIG. 6J do not include the gate cut region and is filled with the gate fill metal. Examples of the gate fill metal include tungsten, cobalt, titanium and ruthenium

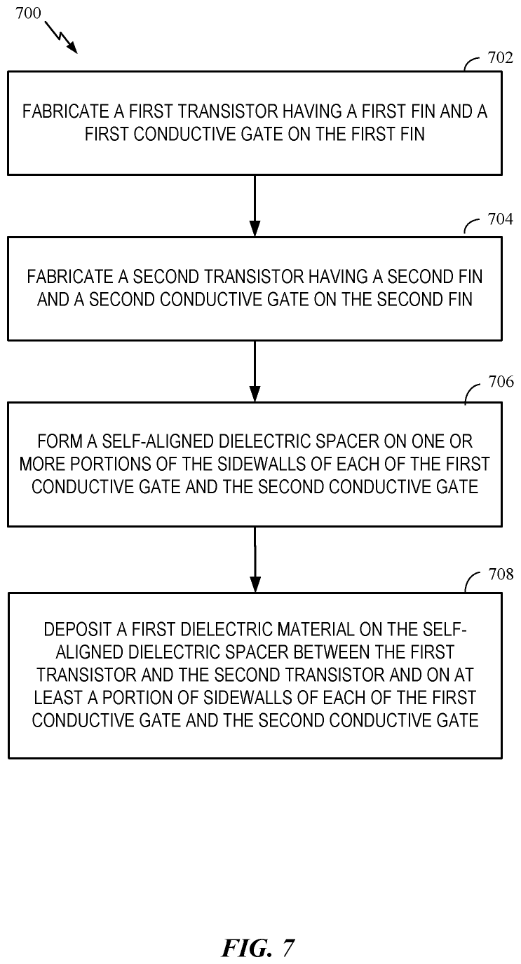

FIG. 7 illustrates a method 700 for fabricating a transistor array. In block 702, a first transistor (e.g., a first fin field effect transistor (FinFET)) having a first fin and a first conductive gate on the first fin is fabricated. In block 704, a second transistor (e.g., a second FinFET) having a second fin and a second conductive gate on the second fin is fabricated. In block 706, a self-aligned dielectric spacer is formed on one or more portions of the sidewalls of each of the first conductive gate and the second conductive gate. In block 708, a first dielectric material is deposited on the self-aligned dielectric spacer between the first transistor and the second transistor. The first dielectric material is also on one or more portions of sidewalls of each of the first conductive gate and the second conductive gate.

According to a further aspect of the present disclosure, a transistor array is described. The transistor array includes means for insulating the first transistor from the second transistor. The insulating means may be the dielectric 512, shown in FIGS. 5, 6H, 61, and 6J. In another aspect, the aforementioned means may be any module or any apparatus configured to perform the functions recited by the aforementioned means.

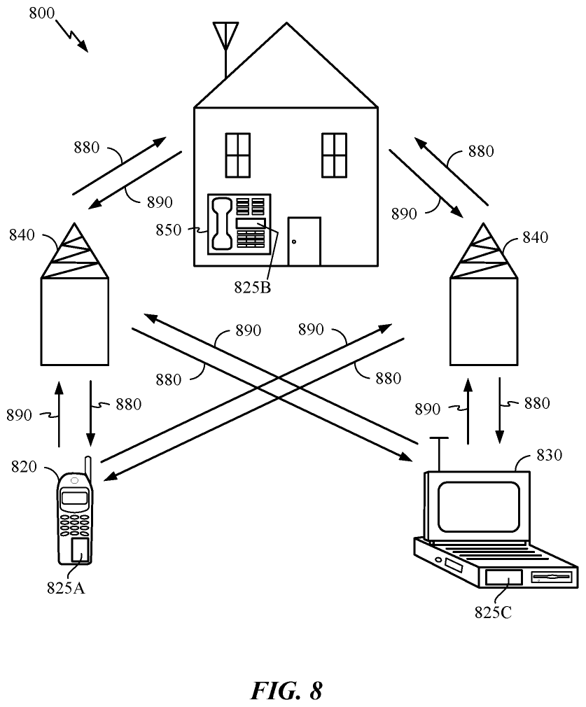

FIG. 8 is a block diagram showing an exemplary wireless communication system 800 in which an aspect of the disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825C, and 825B that include the disclosed transistor array. It will be recognized that other devices may also include the disclosed transistor array, such as the base stations, switching devices, and network equipment. FIG. 8 shows forward link signals 880 from the base station 840 to the remote units 820, 830, and 850 and reverse link signals 890 from the remote units 820, 830, and 850 to base stations 840.

In FIG. 8, remote unit 820 is shown as a mobile telephone, remote unit 830 is shown as a portable computer, and remote unit 850 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the disclosed transistor array.

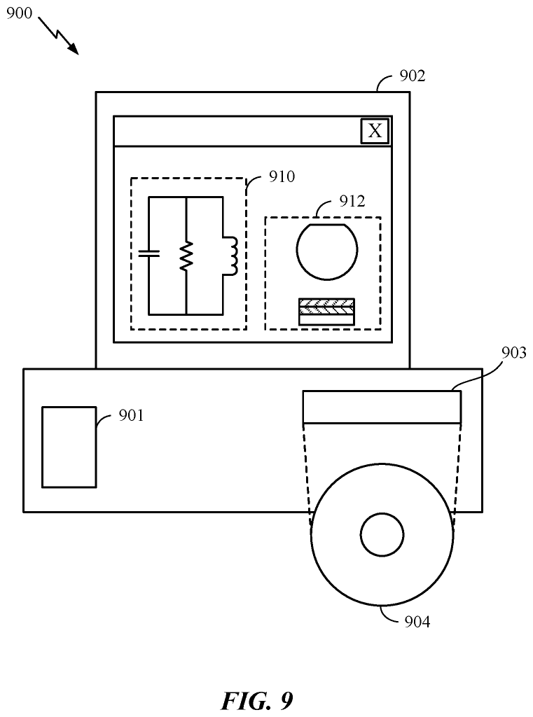

FIG. 9 is a block diagram illustrating a design workstation used for circuit, layout, and logic design of a semiconductor component, such as the transistor array disclosed above. A design workstation 900 includes a hard disk 901 containing operating system software, support files, and design software such as Cadence or OrCAD. The design workstation 900 also includes a display 902 to facilitate design of a circuit 910 or a semiconductor component 912 such as a transistor array. A storage medium 904 is provided for tangibly storing the design of the circuit 910 or the semiconductor component 912 including the transistor array. The design of the circuit 910 or the semiconductor component 912 including the transistor array may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the semiconductor component 912 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A transistor array, comprising:
a first transistor having a first fin and a first conductive gate on the first fin;
a second transistor having a second fin and a second conductive gate on the second fin;
a first dielectric material between the first transistor and the second transistor and on at least a portion of sidewalls of each of the first conductive gate and the second conductive gate; and
a self-aligned dielectric spacer on at least a portion of the sidewalls of each of the first conductive gate and the second conductive gate.

2. The transistor array of claim 1, in which the first dielectric material comprises silicon nitride (SiN).

3. The transistor array of claim 1, in which the self-aligned dielectric spacer comprises a low-K dielectric material.

4. The transistor array of claim 3, in which the low-K dielectric material comprises a low-K spin-on material.

5. The transistor array of claim 1, in which the first transistor and the second transistor comprise fin field effect transistors (FinFETs).

6. The transistor array of claim 1, in which the first transistor and the second transistor comprise gate all around transistors.

7. A method for fabricating a transistor array, comprising:
fabricating a first transistor having a first fin and a first conductive gate on the first fin;
fabricating a second transistor having a second fin and a second conductive gate on the second fin;
forming self-aligned dielectric spacers on sidewalls of each of the first conductive gate and the second conductive gate; and
depositing a first dielectric material on the self-aligned dielectric spacers between the first transistor and the second transistor and on at least a portion of sidewalls of each of the first conductive gate and the second conductive gate.

8. The method of claim 7, in which forming the self-aligned dielectric spacers further comprises:
depositing a dielectric protection layer on the first transistor and the second transistor;
etching a gate cut region from the dielectric protection layer between the first transistor and the second transistor; and
recessing the gate cut region.

9. The method of claim 8, further comprising filling the gate cut region that is recessed with the first dielectric material.

10. The method of claim 9, further comprising:
removing the dielectric protection layer; and
depositing a fill gate conductive layer on the first transistor and the second transistor.

11. The method of claim 7, in which depositing the first dielectric material comprises depositing silicon nitride (SiN).

12. The method of claim 7, in which forming self-aligned dielectric spacers comprises forming self-aligned dielectric spacers comprising a low-K dielectric material.

13. The method of claim 7, in which forming self-aligned dielectric spacers comprises forming self-aligned dielectric spacers comprising a low-K spin-on material.

14. The method of claim 7, in which fabricating the first transistor and the second transistor respectively comprises fabricating a first fin field effect transistor (FinFET) and a second FinFET.

15. The method of claim 7, in which fabricating the first transistor and the second transistor respectively comprises fabricating a first gate all around transistor and a second gate all around transistor.

16. A transistor array, comprising:
a first transistor having a first fin and a first conductive gate on the first fin;
a second transistor having a second fin and a second conductive gate on the second fin;
means for insulating the first transistor from the second transistor, the insulating means between the first transistor and the second transistor and on at least a portion of sidewalls of each of the first conductive gate and the second conductive gate; and
a self-aligned dielectric spacer on at least a portion of the sidewalls of each of the first conductive gate and the second conductive gate.

17. The transistor array of claim 16, in which the self-aligned dielectric spacer comprises a low-K dielectric material.

18. The transistor array of claim 17, in which the low-K dielectric material comprises a low-K spin-on material.

19. The transistor array of claim 16, in which the first transistor and the second transistor comprise fin field effect transistors (FinFETs).

20. The transistor array of claim 16, in which the first transistor and the second transistor comprise gate all around transistors.
